(19) United States
(12) Patent Application Publication
(10) Pub. No.: US 2016/0118547 A1
(43) Pub. Date: Apr. 28, 2016

(54) LIGHT-EMITTING DEVICE AND METHOD OF PRODUCING THE SAME

(71) Applicant: STANLEY ELECTRIC CO., LTD., Tokyo (JP)

(72) Inventors: Ryosuke KAWAI, Yokohama-shi (JP); Mamoru MIYACHI, Yokohama-shi (JP)

(73) Assignee: STANLEY ELECTRIC CO., LTD., Tokyo (JP)

(21) Appl. No.: 14/885,130

(22) Filed: Oct. 16, 2015

(30) Foreign Application Priority Data
Oct. 23, 2014 (JP) 2014-216441

(51) Int. Cl. H01L 33/48; H01L 25/00; H01L 33/62; H01L 25/075

(52) U.S. Cl. CPC H01L 33/483; H01L 25/0753; H01L 25/50; H01L 33/62; H01L 2933/0066; H01L 2933/0033

(57) ABSTRACT

A light-emitting device of the present invention includes a plurality of first mounting bonding layers that are formed of a metal on a mounting substrate and disposed separately from each other in an island shape, and a plurality of light-emitting elements that are provided on the first mounting bonding layers, respectively. Each of the light-emitting elements includes a columnar support that is mounted on the first mounting bonding layer, and a light-emitting unit that is located on the top face of the support. Each of the supports has a protrusion at a portion closer to the top face on a side face of the support.

### BACKGROUND OF THE INVENTION

1. Field of the Invention

The present invention relates to a light-emitting device, and in particular, to a light-emitting device provided with a light-emitting element using a light-emitting diode (LED), and a method of producing the same.

2. Description of the Related Art

Conventionally, a light-emitting device provided with a plurality of light-emitting elements has been used as an illumination, a backlight, an industrial apparatus, or the like. A light-emitting element described in Japanese Patent Application Laid-Open No. 2011-100974 is produced as follows. A semiconductor layer of AlGaInP or GaN is epitaxially grown on a growth substrate such as a GaAs substrate or a sapphire substrate by a metal-organic chemical vapor deposition (MOCVD) method, and bonded to a conductive support substrate, and the growth substrate is then removed.

### SUMMARY OF THE INVENTION

In production of a light-emitting device provided with a plurality of such light-emitting elements mounted on a mounting substrate, the light-emitting elements may be bonded to the mounting substrate by metal bonding. In this case, for example, it is necessary that the light-emitting elements be closely arranged to each other. This is because this arrangement can prevent formation of a dark part between the light-emitting elements during lighting of the light-emitting device. However, in the arrangement, a region between the light-emitting elements is filled with a flux that is exuded during the metal bonding, and as a result, a stress is applied to the light-emitting elements. This stress moves or tilts the light-emitting elements. Such a light-emitting device has a problem in which the positions of the light-emitting elements cannot be controlled.

The present invention has been made in view of the circumstances, and it is an object of the present invention to provide a light-emitting device using light-emitting elements that can be closely mounted on a mounting substrate and of which the positions can be favorably controlled and a method for producing the same.

A light-emitting device of the present invention includes a mounting substrate, a plurality of first mounting bonding layers that are formed of a metal on a surface of the mounting substrate and disposed separately from each other in an island shape, and a plurality of light-emitting elements that are provided on the first mounting bonding layers, respectively. In the light-emitting device, each of the light-emitting elements includes a columnar support that is mounted on each of the first mounting bonding layers, and a light-emitting unit that has a semiconductor layer in which a first semiconductor layer of a first conductivity type, a light emitting layer, and a second semiconductor layer of a second conductivity type are layered in this order and is provided on a top face of the support. Each of the supports has a second mounting bonding layer that is bonded to each of the first mounting bonding layers on the bottom face of each of the supports, and a protrusion on a side face of each of the supports that faces an area between the light-emitting elements, said protrusion protruding at a portion closer to the top face.

A method of producing a light-emitting device according to the present invention includes: forming a plurality of first mounting bonding layers that are formed of a metal and disposed separately from each other in an island shape on a mounting substrate; forming a plurality of semiconductor layers that are arranged separately from each other on a growth substrate and forming a first metal bonding layer on each of the semiconductor layers; forming a plurality of second metal bonding layers at positions corresponding to the first metal bonding layers, respectively, on one face of a support substrate; forming a first groove between the second metal bonding layers on said one face of the support substrate; bonding each of the first metal bonding layers to each of the second metal bonding layers; removing the growth substrate; forming second mounting bonding layers of a metal on another face of the support substrate; forming a groove having a larger width than that of the first groove on the other face of the support substrate at an area corresponding to an area where the first groove is formed on said one face of the support substrate so as to reach the bottom of the first groove from the other face, and dividing the supporting substrate into pieces to form a plurality of light-emitting elements; and applying a metal paste to a surface of each of the first mounting bonding layers, mounting each of the light-emitting elements on the surface, and bonding each of the first mounting bonding layers to each of the second mounting bonding layers.

### BRIEF DESCRIPTION OF THE DRAWINGS

A more complete understanding of the present invention will be obtained by referring to the following description and the accompanying drawings.

FIG. 1A is a top view of a light-emitting device of an embodiment of the present invention;

FIG. 1B is a cross-sectional view taken along line 1B-1B in FIG. 1A;

FIG. 2A is a cross-sectional view illustrating a process of producing the light-emitting device of FIGS. 1A and 1B;

FIG. 2B is a cross-sectional view illustrating the process of producing the light-emitting device of FIGS. 1A and 1B;

FIG. 2C is a cross-sectional view illustrating the process of producing the light-emitting device of FIGS. 1A and 1B;

FIG. 2D is a cross-sectional view illustrating the process of producing the light-emitting device of FIGS. 1A and 1B;

FIG. 2E is a cross-sectional view illustrating the process of producing the light-emitting device of FIGS. 1A and 1B;

FIG. 2F is a cross-sectional view illustrating the process of producing the light-emitting device of FIGS. 1A and 1B;

FIG. 2G is a cross-sectional view illustrating the process of producing the light-emitting device of FIGS. 1A and 1B;

FIG. 2H is a cross-sectional view illustrating the process of producing the light-emitting device of FIGS. 1A and 1B;

FIG. 2I is a cross-sectional view illustrating the process of producing the light-emitting device of FIGS. 1A and 1B;

FIG. 3 is a cross-sectional view illustrating a modification of the light-emitting device; and

FIG. 4 is a top view illustrating a modification of the light-emitting device.

### DETAILED DESCRIPTION OF THE INVENTION

Hereinafter, preferred embodiments of the present invention will be described. The embodiments may be appropriately modified or combined. In the following description and the accompanying drawings, components that are substantially identical or equivalent to each other are denoted by the same reference symbols.

### Embodiments

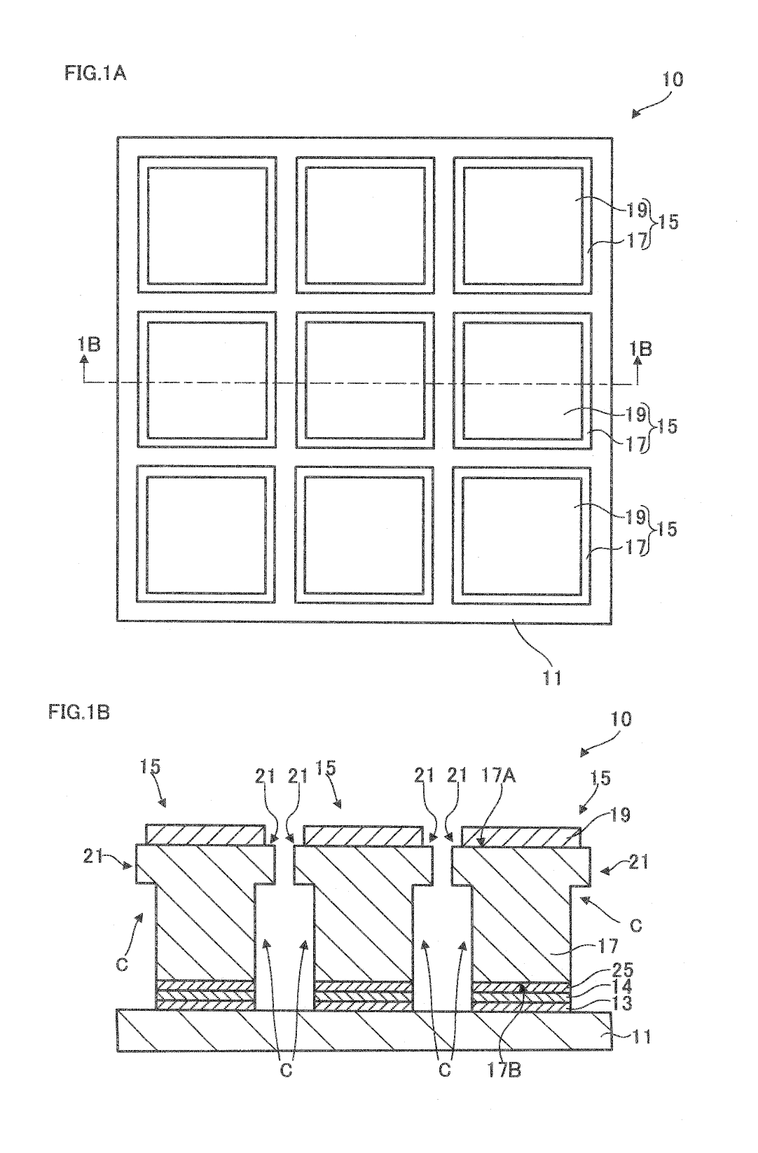

Hereinafter, a light-emitting device 10 according to an embodiment of the present invention will be described as an example of a light-emitting device using an LED element with reference to FIGS. 1A and 1B. A mounting substrate 11 is a substrate formed from a semiconductor such as Si, a metal such as Cu, or an insulating material such as AlN and SiC. Mounting substrate-bonding layers 13 as first mounting bonding layers are each a metal layer formed by layering Ti, Pt, and Au in this order on a top face of the mounting substrate 11. When a metal wiring is formed on the top face of the mounting substrate 11, each of the mounting substrate-bonding layers 13 may be formed by layering a layer at the same layer level as the metal wiring on the mounting substrate 11, followed by patterning, or each of the mounting substrate-bonding layers 13 may be formed on the formed metal wiring. The mounting substrate-bonding layers 13 have a rectangular shape, and are arranged separately in a matrix of 3×3. A bonding-aid layer 14 formed from AuSn is formed on each of the mounting substrate-bonding layers 13.

A light-emitting element 15 is provided on each of the mounting substrate-bonding layers 13 of the mounting substrate 11. Therefore, the light-emitting elements 15 are arranged in the matrix on the mounting substrate 11. Each of the light-emitting elements 15 has a support 17 and a light-emitting unit 19 including a semiconductor layer having a light-emitting layer (not shown) that is bonded to a top face 17A of the support 17.

For example, the support 17 is formed from a conductive substrate of Si or the like. The support 17 has a substantially rectangular parallelepiped shape with a square top face 17A and a square bottom face 17B. The support 17 has a notched recess C on each side face. The notched recess C has a shape in which each side face is notched from the bottom face 17B side. The bottom face 17B of the support 17 is smaller than the top face 17A. Therefore, the support 17 has a protrusion 21 that protrudes outward in a direction parallel to the top face 17A at the upper portion of the support 17.

Specifically, the support 17 has the protrusion 21 at a portion closer to the top face 17A on each side face that faces an adjacent area between the light-emitting elements 15.

The side faces of the supports 17 of the adjacent light-emitting elements 15 are spaced apart at a portion having no protrusion 21, as compared with a portion having the protrusion 21 in a vicinity of the top face 17A. In other words, a space formed below the portion having the protrusion 21 between the adjacent supports 17 is larger than a space formed between the protrusions 21 of the adjacent supports 17. The space formed below the portion having the protrusion 21, that is, formed by the protrusion 21 and the notched recesses C functions as an escape of a flux that is exuded from a metal paste containing the flux used during bonding of each of the light-emitting elements 15 and the mounting substrate 11.

A bottom face-bonding layer 25 as a second mounting bonding layer is formed on the bottom face 17B of each of the supports 17 so as to cover the bottom face 17B. The bottom face-bonding layer 25 is formed on a face opposite to the face having the light-emitting unit 19 of each of the supports 17. The bottom face-bonding layer 25 is a metal layer formed by layering Ti, Pt, and Au in this order on the bottom face 17B. Each of the bottom face-bonding layers 25 is bonded to each of the mounting substrate-bonding layers 13 through each of the bonding-aid layers 14.

Each of the light-emitting units 19 including the semiconductor layer having the light-emitting layer (not shown) is formed on the top face 17A of each of the supports 17. Each of the light-emitting units 19 has a top electrode (not shown). The top electrode is connected to an external electrode through a bonding wire (not shown). Specifically, an electric power is supplied to the light-emitting elements 15 through the metal wiring (not shown) on the mounting substrate 11 and the bonding wire (not shown).

In order to prevent formation of a dark part between the light-emitting elements 15 during lighting of the light-emitting device 10, it is preferable that each of the light-emitting units 19 have a larger area than that of the bottom face 17B of each of the supports 17 as shown in FIG. 1B viewed from the top.

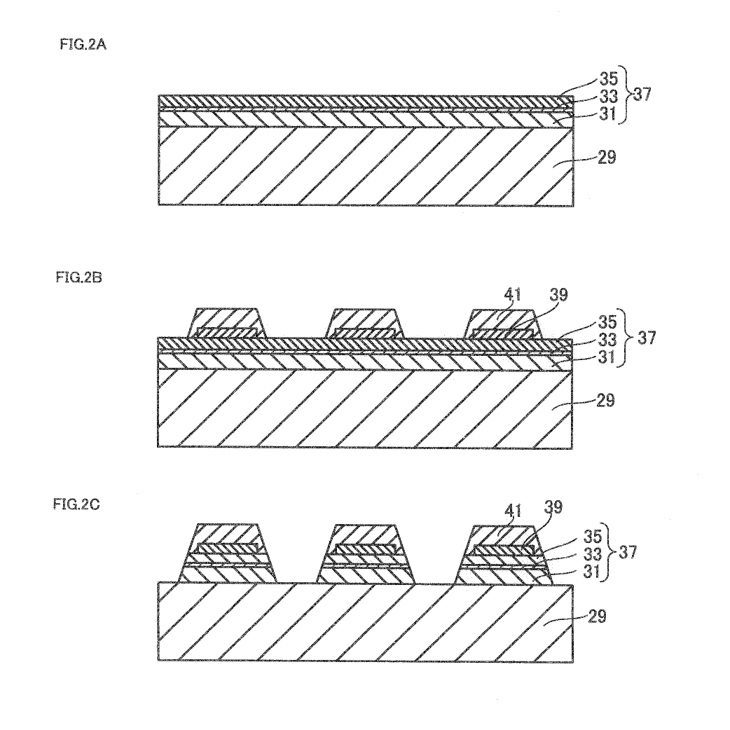

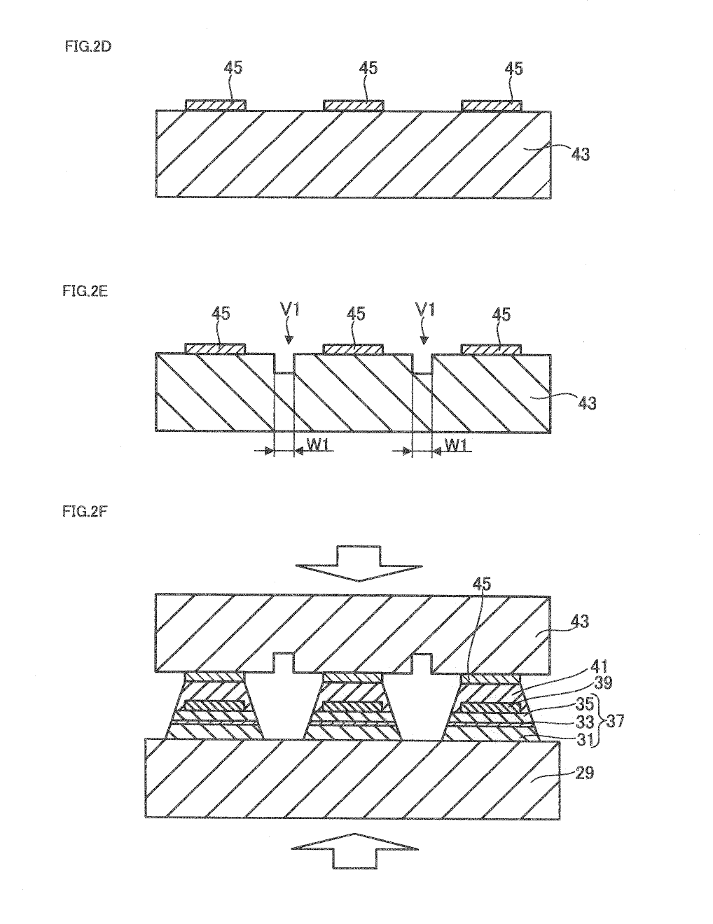

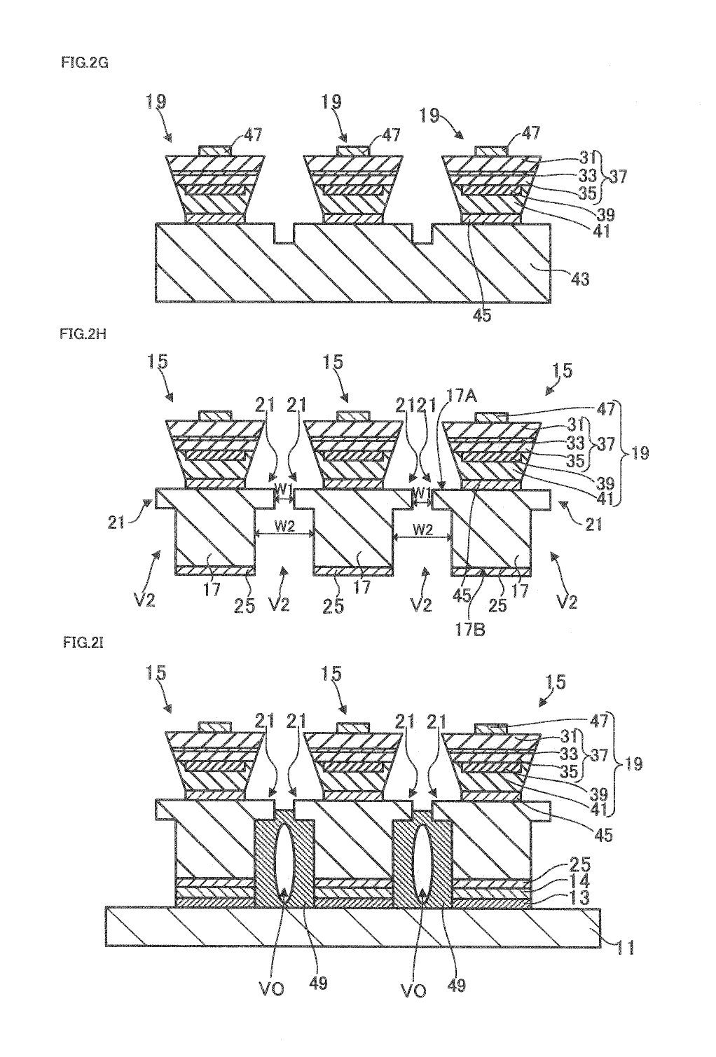

Hereinafter, a method of producing the light-emitting device 10 according to the embodiment of the present invention will be described with reference to FIGS. 2A to 21. FIGS. 2A to 2I are each a cross-sectional view of each process in production of the light-emitting device 10. For clarity, FIGS. 2A to 2I show cross sections of three light-emitting elements. However, in actual production, a sheet in which a large number of light-emitting elements are arranged may be produced.

First, a growth substrate 29 that is a C-plane sapphire substrate is prepared. A semiconductor layer 37 in which an n-type semiconductor layer 31, a light-emitting layer 33, and a p-type semiconductor layer 35 that are made of AlₓIn_{y}Ga_{z}N (0≦x≦1, 0≦y≦1, 0≦z≦1, x+y+z=1) are layered in this order, as shown in FIG. 2A, is crystal-grown by MOCVD.

Specifically, the growth substrate 29 is placed in an MOCVD device, and heated in a hydrogen atmosphere at 1,000° C. for 10 minutes to perform thermal cleaning. Subsequently, TMG and NH₃ are supplied at about 500° C. to form a GaN layer as a low-temperature buffer layer. The temperature is then raised to 1,000° C. and maintained for about 30 seconds to crystallize the low-temperature buffer layer. While the temperature is maintained at 1,000° C., TMG and NH₃ are supplied to form an underlaying GaN layer having a thickness of about 1 μm. Further, TMG, NH₃, and SiH₄ are supplied to grow an n-GaN layer to have a thickness of about 7 μm. In this manner, the n-type semiconductor layer 31 is formed.

Next, at about 700° C., TMG and TMI are supplied to grow an InGaN well layer having a thickness of 2.2 nm, and TMG and NH₃ are supplied to grow a GaN barrier layer having a thickness of 15 nm. These operations are repeated in an alternating manner 5 times to grow InGaN/GaN. Thus, the light-emitting layer 33 having a multiple quantum well structure of InGaN/GaN is formed on the n-type semiconductor layer 31.

Next, the temperature is raised to 870° C., and TMG, TMA, NH₃, and Cp₂Mg are supplied to grow a p-AlGaN clad layer to have a thickness of about 40 nm. Further, TMG, NH₃, and Cp₂Mg are supplied to grow a p-GaN layer to have a thickness of about 150 nm. Thus, the p-type semiconductor layer 35 is formed.

As shown in FIG. 2B, each reflection electrode layer 39 as a p electrode and each semiconductor-side bonding layer 41 as a first metal bonding layer are formed. Specifically, an Ag layer is formed at each of portions for forming the light-emitting units 19 (see FIGS. 1A and 1B) on the semiconductor layer 37, for example, by photolithography, vacuum evaporation, or sputtering. Thus, the reflection electrode layers 39 are formed. Since the reflection electrode layers 39 reflect light emitted from the light-emitting layer 33 to enhance the light extraction efficiency, it is preferable that the reflection electrode layers 39 be formed from a material having high light reflectivity such as Ag or an Ag alloy.

After that, a TIW layer is formed on the p-type semiconductor layer 35 by sputtering so as to cover each of the reflection electrode layers 39, thereby forming a diffusion prevention layer. Ti, Pt, and Au are deposited in this order on the diffusion prevention layer by an electron-beam evaporation method. Thus, the semiconductor-side bonding layers 41 are formed. The semiconductor-side bonding layers 41 are each a layer that is bonded to a support-side bonding layer formed on a support substrate in bonding to the supporting substrate to be described later.

As shown in FIG. 2C, each groove is formed by dry etching including RIE, so as to extend from a surface of the semiconductor layer 37 that is not covered with the semiconductor-side bonding layers 41 to the top face of the growth substrate 29. Thus, each of portions for forming the light-emitting units 19 (see FIG. 1B) is formed.

As shown in FIG. 2D, a support substrate 43 is prepared. The support substrate 43 is a conductive substrate formed of Si or the like. Each support-side bonding layer 45 is formed as a second metal bonding layer on a top face of the support substrate 43 at each position for locating each of the light-emitting units 19. The support-side bonding layers 45 are formed by layering Ti, Pt, and Au in this order by an EB evaporation method or the like.

As shown in FIG. 2E, each first groove V1 having a width W1 is formed between the support-side bonding layers 45 by dry etching using a resist film as a mask so that a region where the support-side bonding layers 45 are formed on the top face of the support substrate 43 is divided. Specifically, the first grooves V1 are formed on the surface of the support substrate 43 so as to surround each of the support-side bonding layers 45.

The first grooves V1 may be formed by wet etching using a resist film, laser dicing, or blade dicing. For example, the first grooves V1 are formed so that the depth is about one-fifth of the thickness of the support substrate 43.

The processes of forming the support-side bonding layers 45 and the first grooves V1 on the support substrate 43 as shown in FIG. 2E may be performed before processes described with reference to FIGS. 2A to 2C as above.

As shown in FIG. 2F, the surface of each of the support-side bonding layers 45 is brought into contact with the surface of each of the semiconductor-side bonding layers 41. For example, while the bonding layers are pressed against each other, the bonding layers are thermocompression-bonded at 200° C. over 1 hour. Thus, the bonding layers are bonded, and the support substrate 43 is bonded to the semiconductor layer. After that, the growth substrate 29 is irradiated with excimer laser from a back side thereof by a laser lift off (LLO) system and removed. The removal of the growth substrate 29 is not limited to laser lift off (LLO), and may be performed by wet etching, dry etching, mechanical polishing, chemical mechanical polishing (CMP), or a combination of at least two thereof.

Subsequently, an insulating protective layer (not shown) is formed so as to cover a top face and side faces of the semiconductor layer 37. For example, an SiO₂ layer that is an insulating oxide is formed by sputtering. Thus, the insulating protective layer is formed. The insulating protective layer is not formed at a region for forming a top electrode 47, described later, on the semiconductor layer 37. For the insulating protective layer, an insulator of an oxide other than SiO₂, such as Al₂O₃, Ti₂O₃, TiO₂, HfO₂, and CeO₂, may be used.

Before the formation of the insulating protective layer, the surface of the n-type semiconductor layer 31 may be immersed in an alkaline solution such as a KOH solution to form an uneven structure derived from a semiconductor crystal structure. This uneven structure improves the light extraction efficiency from the semiconductor layer 37.

As shown in FIG. 2G, a resist mask having an opening is formed by photolithography so that a portion of the semiconductor layer 37 that is not covered with the insulating protective layer is exposed. Ti, Al, Ti, Pt, and Au are layered in this order by an EB evaporation method or the like, and the resist mask is removed to form the top electrode 47 as an n electrode. Thus, each of the light-emitting units 19 is completed.

As shown in FIG. 2H, each bottom face-bonding layer 25 as a second mounting layer is formed on a bottom face of the support substrate 43, which is opposite to a face bonded to the light-emitting units 19. Each second groove V2 is formed so as to reach a bottom of each of the first grooves V1 from the bottom face of the support substrate 43. As a result, the support substrate 43 is divided into pieces to form supports 17. The divided pieces are the individual light-emitting elements 15.

Specifically, a thermal oxide film on a bottom surface of the support substrate 43 where each of the bottom face-bonding layers 25 is formed is first removed by grinding, wet etching, or dry etching. After that, the resist mask having an opening is formed so that each area for forming each of the bottom face-bonding layers 25 is exposed, and patterned. Ti, Pt, and Au are layered in this order by an EB evaporation method or the like.

Subsequently, each second groove V2 that has a wider width W2 than that of each of the first grooves V1 and reaches the bottom of each of the first grooves V1 from the bottom face side of the support substrate 43 is formed by blade dicing at each area on the bottom face that corresponds to each area where each of the first grooves V1 is formed on the top face.

Therefore, the support substrate 43 is cut by blade dicing so that a center line of each of the second grooves V2 and a center line of each of the first grooves V1 overlap as viewed from the top and each of the second grooves V2 reaches the bottom of each of the first grooves V1. The second grooves V2 may be formed by dry etching or wet etching using a resist film or laser dicing. Thus, the support substrate 43 is cut. The divided light-emitting elements 15 are completed.

Since the width W2 of the second grooves V2 is lager than the width W1 of the first grooves V1, as described above, the bottom face 17B of the support 17 of the divided light-emitting element 15 is smaller than the top face 17A thereof. Therefore, the protrusion 21 and the notched recess C (see FIG. 1B) are formed. Each of the second grooves V2 is formed in the outermost side faces of the support substrate 43 so as to form the same structure of the protrusion 21 that is formed in each side face of each support 17 that faces the adjacent light-emitting elements 15.

As shown in FIG. 2I, the light-emitting elements 15 are mounted on the mounting substrate 11. Specifically, Ti, Pt, and Au are first layered on the mounting substrate 11 by an EB evaporation method or the like to form a plurality of mounting substrate-bonding layers 13. The mounting substrate-bonding layers 13 each have a rectangular shape corresponding to the shape of the bottom face-bonding layer 25 of each of the light-emitting elements 15. The mounting substrate-bonding layers 13 are arranged separately from each other in a matrix of 3×3 on the mounting substrate 11.

After that, an AuSn paste containing AuSn powder and a flux is applied to a top face of each of the mounting substrate-bonding layers 13 to form each bonding-aid layer 14. Each of the light-emitting elements 15 is placed on each of the bonding-aid layers 14 so that each surface of the bonding-aid layers 14 and each surface of the bottom face-bonding layers 25 are opposed.

While the mounting substrate 11 and the light-emitting elements 15 are pressed against each other, the bonding layers are molten-bonded at 200° C., for example. Thus, the light-emitting elements 15 are mounted on the mounting substrate 11. At that time, the light-emitting elements 15 are self-aligned by the surface tension of the dissolved AuSn paste so that each side of each of the mounting substrate-bonding layers 13 is parallel to each corresponding side of each of the bottom face-bonding layers 25.

In order to enhance the effect of the self alignment, it is preferable that each of the bottom face-bonding layers 25 be not formed on the whole bottom face 17B of each of the supports 17 and be formed apart from an end of the bottom face 17B so as to be smaller than the bottom face 17B as viewed from the top. Further, it is preferable that the planar shapes of the mounting substrate-bonding layers 13 and the bottom face-bonding layers 25 be the same.

A flux 49 shown in FIG. 21 is exuded (eluted) from the AuSn paste that forms the bonding-aid layers 14 in a molten-bonding process of the mounting substrate 11 and the light-emitting elements 15. As shown in FIG. 21, the flux 49 eluted by heat in the molten-bonding process is exuded between the supports 17 of the adjacent light-emitting elements 15.

In the light-emitting device 10, the distance between the side faces of the supports 17 of the adjacent light-emitting elements 15 is larger at a portion below the protrusion 21, that is, a portion where the notched recess C (see FIG. 1B) is formed. Even when the light-emitting elements 15 are arranged closely, a large space is formed below the protrusion 21. Therefore, the flux is not filled gradually on the surface of the mounting substrate 11, that is, upward from the lower portion, and moves upward along the side faces of the supports 17 by the surface tension.

As shown in FIG. 21, the flux 49 is eluted and exuded during the molten-bonding, and filled gradually from the lower portion in a space between the adjacent supports 17, but not completely filled in the space. The flux 49 is partially filled so as to have a void VO inside, and then evaporated and vanished.

After the bonding of the mounting substrate 11 and the light-emitting elements 15, each top electrode 47 and an external electrode (not shown) on the mounting substrate 11 are connected through a wire bonding. After the bonding of the mounting substrate 11 and the light-emitting elements 15, the light-emitting elements 15 may be sealed by a phosphor resin on the mounting substrate 11 so as to be embedded therein.

As described above, in the production of the light-emitting device 10 of the present invention, the space that is formed by the protrusion 21 and the notched recess C functions as an escape of the flux during the molten-bonding of the mounting substrate 11 and the light-emitting elements 15. The flux 49 is not completely filled in the space between the supports 17. Therefore, a stress applied to the side faces of the supports 17 by the eluted flux 49 during the molten-bonding can be decreased, and a shift in position and a tilt of the light-emitting elements 15 during the molten-bonding can be prevented.

Even when the flux 49 is filled in the space between the supports 17 from the lower portion during the molten-bonding, the flux is not completely filled in the space. This is because the space below the protrusion 21 is large enough to accommodate the eluted flux. Accordingly, even in this case, a stress applied to the side faces of the supports 17 by the eluted flux 49 during the molten-bonding can be decreased, and a shift in position and a tilt of the light-emitting elements 15 during the molten-bonding can be prevented.

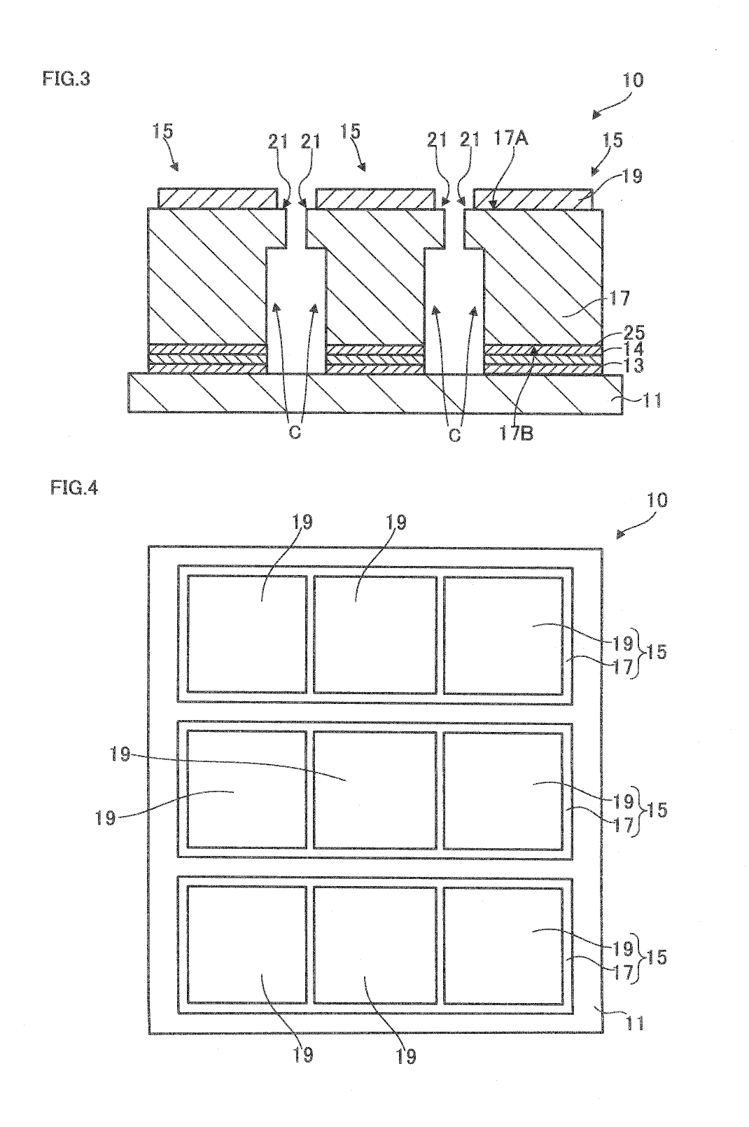

In the embodiment described above, a case where the protrusion 21 and the notched recess C are formed on all the side faces of each of the supports 17 of the light-emitting elements 15 has been described as an example. However, as shown in FIG. 3, the protrusion 21 and the notched recess C may be formed on only a side face that faces an area between the adjacent light-emitting elements 15 during mounting on the light-emitting device 10.

Among side faces of each of the supports of the light-emitting elements 15 arranged at the outermost periphery on the mounting substrate 11, the protrusion 21 and the notched recess C may not be formed on a side face that does not face the light-emitting elements 15. Therefore, it is not necessary that the grooves are formed at the outermost periphery in the support substrate 43 during formation of the second grooves V2 described above with reference to FIG. 2H.

Further, in the embodiment described above, a case where each one of the light-emitting units 19 is formed on each one of the supports 17 and the light-emitting elements 15 are arranged in a matrix of 3×3 on the mounting substrate 11 has been described as an example. However, a plurality of light-emitting units 19 may be formed on one support 17. In addition, the arrangement of the light-emitting elements 15 is not limited to a matrix.

For example, as shown in FIG. 4, a single light-emitting element 15 may be formed such that a plurality of light-emitting units 19 are formed on each of the supports 17, and a plurality of the light-emitting elements 15 may be arranged in a line on the mounting substrate 11. The light-emitting units 19 may be arranged in various manners such as in lines and in a matrix. The light-emitting elements 15 may also be arranged on the each of the supports in lines on the mounting substrate 11. This arrangement is not limited.

When a plurality of light-emitting units 19 are formed on each of the supports 17, it is necessary that the first grooves V1 be formed so as to surround a region including the plurality of light-emitting units 19 in the process of forming the first grooves V1 described in FIG. 2E.

In the embodiment described above, a case where each of the supports 17 has a substantially rectangular parallelepiped shape with a square top face has been described as an example. The top face of each of the supports 17 may be a rectangle other than a square, as shown in FIG. 4. Further, each of the supports 17 may have a cylindrical shape or a polygonal column shape other than a quadrangular prism shape, such as a pentagonal prism shape and a hexagonal prism shape.

In the embodiment described above, each of the supports 17 illustrated in the cross-sectional view has a side face of bending contour. However, each of the supports 17 may have a side face of continuous curvilinear contour.

When the light-emitting units 19 are formed on a top face 17A of each one of the supports 17, it is preferable that a region where the light-emitting units 19 are present as viewed from the top be over a wider region than a bottom face 17B of each of the supports 17.

In the embodiment described above, the light-emitting elements having a semiconductor element structure in which an n electrode and a p electrode are formed on the respective opposite surfaces has been described. However, the present invention can be applied to even an element having another semiconductor element structure. For example, the present invention can be applied to a light-emitting element having a semiconductor element structure in which an n electrode and a p electrode are formed on one surface of the semiconductor layer so as to be exposed on the one surface of the semiconductor. In this case, for example, the n electrode may be a Via structure electrode. Specifically, the n electrode may have a structure in which a hole Via that penetrates from the surface of the p-type semiconductor layer through the p-type semiconductor layer and the light-emitting layer to the n-type semiconductor layer is formed, and the n electrode that is connected to the n-type semiconductor layer exposed in the hole Via and exposed through the hole Via is formed.

For example, when the n electrode and the p electrode are formed so as to face each of the supports 17, the supports 17 are formed from an insulating material and a wiring is formed on the supports 17, or an insulating layer such as a thermal oxide film is formed on the top face of each of the supports 17 formed from a conductive material and the support side-bonding layers 45 and a wiring are formed on the insulating layer. In this case, an opening may be formed on a part of the insulating layer formed on the top face of each of the supports 17 to make the support side-bonding layers 45 (see FIG. 21) and the supports 17 electrically conductive therebetween.

Further, the wiring and an external electrode may be connected through a bonding wire. Thus, an electricity is supplied to the light-emitting elements 15.

In the embodiment described above, a case where the mounting substrate 11 is a substrate formed from an insulating material has been described as an example. However, a material for the substrate may be appropriately selected. For example, for the material for the mounting substrate 11, a conductive material such as alumina and a ceramic material may be selected, or an insulating material such as a glass epoxy substrate having a through hole made of Cu, Ag, or the like may be selected.

As described above, when the wiring, the external electrode, materials for the support and the mounting substrate, and the like are appropriately selected, a method of driving a light-emitting element can be optionally changed into separate driving or collective driving.

In the embodiment described above, the same light-emitting elements 15 are mounted on the mounting substrate 11. However, various types of light-emitting elements 15 having different light-emitting colors may be mounted. For example, light-emitting elements 15 having light-emitting layers that each emit red light, green light, and blue light may be mounted. In this case, the light-emitting device 10 is used as an RGB light source.

In the embodiment described above, a case where the light-emitting elements 15 are each an LED element has been described as an example. However, the light-emitting elements 15 may be a light-emitting element having a light-emitting unit 19 of different configuration, such as an organic EL element.

In the embodiment, various values, dimensions, materials, and the like are merely exemplary, and can be appropriately selected according to application, a semiconductor element to be produced, and the like.

It is to be understood by those skilled in this art that various changes and modifications of the embodiment herein may be made easily. Such changes and modifications can be made without departing from the spirit and scope of the present invention and without impairing its intended advantages. It is therefore intended that all such changes and modifications be covered by the present application.

This application is based on Japanese Patent Application No. 2014-216441, filed on Oct. 23, 2014, the content of which is incorporated by reference herein.

What is claimed is:

1. A light-emitting device comprising:
a mounting substrate;
a plurality of first mounting bonding layers that are formed of a metal on a surface of the mounting substrate and disposed separately from each other in an island shape; and
a plurality of light-emitting elements that are provided on the first mounting bonding layers, respectively, wherein
each of the light-emitting elements includes
a columnar support that is mounted on each of the first mounting bonding layers, and
a light-emitting unit that has a semiconductor layer in which a first semiconductor layer of a first conductivity type, a light emitting layer, and a second semiconductor layer of a second conductivity type are layered in this order and is provided on a top face of the support,
each of the supports has a second mounting bonding layer that is bonded to each of the first mounting bonding layers on the bottom face, and
a protrusion on a side face of each of the supports that faces an area between the light-emitting elements, said protrusion protruding at a portion closer to the top face.

2. The light-emitting device according to claim 1, wherein a plurality of the light-emitting units are arranged on each of the supports.

3. The light-emitting device according to claim 2, wherein the light-emitting elements are arranged in a matrix on the mounting substrate.

4. The light-emitting device according to claim 3, wherein the light-emitting units are formed in a larger region than a bottom face of each of the supports as viewed from the top.

5. A method of producing a light-emitting device, comprising:
forming a plurality of first mounting bonding layers that are formed of a metal and disposed separately from each other in an island shape on a mounting substrate;
forming a plurality of semiconductor layers that are arranged separately from each other on a growth substrate and forming a first metal bonding layer on each of the semiconductor layers;
forming a plurality of second metal bonding layers at positions corresponding to the first metal bonding layers, respectively, on one face of a support substrate;
forming a first groove between the second metal bonding layers on said one face of the support substrate;
bonding each of the first metal bonding layers to each of the second metal bonding layers;
removing the growth substrate;
forming second mounting bonding layers of a metal on another face of the support substrate;
forming a groove having a larger width than that of the first groove on the other face of the support substrate at an area corresponding to an area where the first groove is formed on said one face of the support substrate so as to reach the bottom of the first groove from the other face, and dividing the supporting substrate into pieces to form a plurality of light-emitting elements; and
applying a metal paste to a surface of each of the first mounting bonding layers, mounting each of the light-emitting elements on the surface, and bonding each of the first mounting bonding layers to each of the second mounting bonding layers.

6. The method of producing a light-emitting device according to claim 5, wherein in the forming of the first groove, the first groove is formed so as to surround at least two of the second metal bonding layers.

7. The method of producing a light-emitting device according to claim 6, wherein the first mounting bonding layers are arranged in a matrix on the mounting substrate.

8. The method of producing a light-emitting device according to claim 7, wherein the metal paste contains a metal powder and a flux, the bonding for the first and second mounting bonding layers is performed by a molten-bonding process, and the flux eluted at a region between the adjacent supports during the molten-bonding process forms a void at the region.
